(19) United States
(12) Patent Application Publication
(10) Pub. No.: US 2012/0043122 A1
(43) Pub. Date: Feb. 23, 2012

(54) BOARD WITH FINE PITCH BUMP AND METHOD OF MANUFACTURING THE SAME

(75) Inventor: Jin Ho KIM, Gyeonggi-do (KR)

(73) Assignee: SAMSUNG ELECTRO-MECHANICS CO., LTD., Suwon (KR)

(21) Appl. No.: 13/212,651

(22) Filed: Aug. 18, 2011

(30) Foreign Application Priority Data
Aug. 18, 2010 (KR) 10-2010-0079832

(51) Int. Cl. H05K 1/09; H05K 3/40

(52) U.S. Cl. 174/257; 29/852

(57) ABSTRACT

Disclosed herein are a board with a fine pitch bump and a method of manufacturing the same. The method of manufacturing a board with a fine pitch bump includes: forming a solder resist layer by stacking a solder resist on a core layer having a circuit pattern formed thereon; forming a seed layer on an upper surface of the solder resist layer; forming a dry film layer by stacking a dry film on an upper surface of the seed layer; forming holes by simultaneously drilling the solder resist layer, the seed layer, and the dry film layer; and forming a copper post bump by performing copper filling plating in the holes and removing the seed layer and the dry film layer. The holes having the same size are simultaneously drilled into the solder resist layer and the dry film layer to improve a matching degree of the copper post bump, thereby making it possible to form the fine pitch bump.

### CROSS REFERENCE(S) TO RELATED APPLICATIONS

This application claims the benefit under 35 U.S.C. Section 119 of Korean Patent Application Serial No. 10-2010-0079832 entitled “Board With Fine Pitch Bump And Method Of Manufacturing The Same” filed on Aug. 18, 2010, which is hereby incorporated by reference in its entirety into this application.

### BACKGROUND OF THE INVENTION

1. Technical Field

The present invention relates to a board with a fine pitch bump and a method of manufacturing the same, and more particularly, to a board with a fine pitch bump in which holes having the same size are simultaneously drilled into a stacked solder resist (SR) layer and a dry film (DF) layer at the time of manufacturing the board to improve a matching degree of a copper post bump, such that the fine pitch bump may be formed, and a method of manufacturing the same.

2. Description of the Related Art

In accordance with the trend toward an electronic device having a high performance and a compact size, the number of semiconductor chip terminals has significantly increased. Therefore, a package board has been thinned in order to improve a signal transfer speed.

Accordingly, a pitch of a bump connecting the board to a chip has also become fine. As a technology capable of making the pitch of the bump fine, a copper post bumping technology has been developed.

### SUMMARY OF THE INVENTION

An object of the present invention is to provide a board with a fine pitch bump in which holes are simultaneously drilled into a solder resist layer and a dry film layer at the time of manufacturing the board to thereby form the fine pitch bump using a copper post bumping technology, which is a technology capable of making a pitch of a bump fine, and a method of manufacturing the same.

According to an exemplary embodiment of the present invention, there is provided a method of manufacturing a board with a fine pitch bump, the method including: forming a solder resist layer by stacking a solder resist on a core layer having a circuit pattern formed thereon; forming a seed layer on an upper surface of the solder resist layer; forming a dry film layer by stacking a dry film on an upper surface of the seed layer; forming holes by simultaneously drilling the solder resist layer, the seed layer, and the dry film layer; and forming a copper post bump by performing copper filling plating in the holes and removing the seed layer and the dry film layer.

The holes may be formed to have the same width in the solder resist layer, the seed layer, and the dry film layer.

The circuit pattern may be formed on an upper surface or a lower surface of the core layer.

The solder resist may be stacked on an upper surface or a lower surface of the core layer.

According to another exemplary embodiment of the present invention, there is provided a board with a fine pitch bump, the board including: a core layer having a circuit pattern formed thereon; a solder resist layer stacked on an upper surface or a lower surface of the core layer; a seed layer formed on an upper surface of the solder resist layer; a dry film layer formed on an upper surface of the seed layer; holes penetrating through the solder resist layer, the seed layer, and the dry film layer; and a copper post bump formed by performing copper filling plating in the holes.

The holes may be formed to have the same width in the solder resist layer, the seed layer, and the dry film layer.

The circuit pattern may be formed on an upper surface or a lower surface of the core layer.

The solder resist layer may be stacked on the upper surface or the lower surface of the core layer.

### BRIEF DESCRIPTION OF THE DRAWINGS

FIGS. 1 to 5 are cross-sectional views sequentially showing a process of manufacturing a board with a fine pitch pump according to an exemplary embodiment of the present invention.

### DESCRIPTION OF THE PREFERRED EMBODIMENTS

Hereinafter, exemplary embodiments of the present invention will be described in detail with reference to a board with a fine pitch bump. The exemplary embodiments of the present invention to be described below are provided by way of example so that the idea of the present invention can be sufficiently transferred to those skilled in the art to which the present invention pertains. Therefore, the present invention is not be limited to the exemplary embodiments set forth herein but may be modified in many different forms. In the drawings, the size and the thickness of the apparatus may be exaggerated for the convenience. Like reference numerals denote like elements throughout the specification.

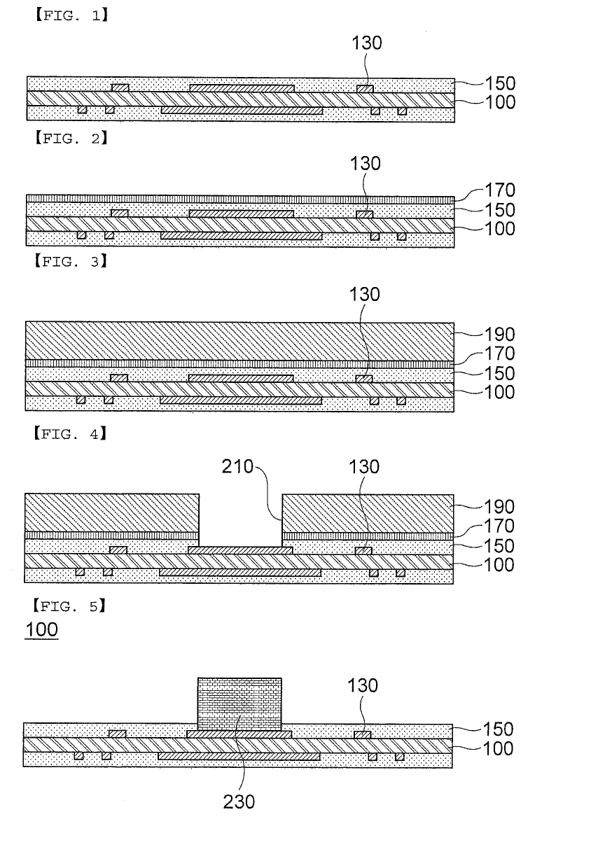

FIGS. 1 to 5 are cross-sectional views sequentially showing a process of manufacturing a board with a fine pitch pump according to an exemplary embodiment of the present invention.

As shown in FIGS. 1 to 5, a board 100 with a fine pitch bump includes a core layer 110, a solder resist layer 150, a seed layer 170, a dry film (DF) layer 190, holes 210, and a copper post bump 230.

More specifically, the core layer 110 may have the circuit pattern 130 formed on an upper surface thereof.

Here, the circuit pattern 130 may be formed on the upper surface or a lower surface of the core layer 110.

The solder resist layer 150 may be stacked on an upper surface or a lower surface of the core layer 110.

The seed layer 170 may be formed on an upper surface of the solder resist layer 150.

The dry film layer 190 may be formed on an upper surface of the seed layer 170.

The holes 210 may be formed to penetrate through the solder resist layer 150, the seed layer 170, and the dry film layer 190.

Here, the holes may be formed to have the same width in the solder resist layer 150, the seed layer 170, and the dry film layer 190. Since the holes are formed to have the same width in the solder resist layer and the dry film layer, a post bump in one unit may be subsequently formed.

The copper post bump 230 may be formed by performing copper filling plating in the holes 210.

Here, since the copper post bump 230 is formed by performing the copper filling plating in through holes formed to have the same width in the solder resist layer 150, the seed layer 170, and the dry film layer 190, it may be formed in a shape in one unit, such that a size of a bump die may be reduced, as compared to the case according to the related art. In addition, a fine pitch bump may be formed due to the reduction in the size of the bump die.

Hereinafter, although not shown, a method of manufacturing a board with a fine pitch bump will be described.

First, in the board 100 with a fine pitch bump, the solder resist layer 150 may be formed by stacking a solder resist on the core layer 110 having the circuit pattern 130 formed thereon.

Here, the circuit pattern 130 may be formed on the upper surface or the lower surface of the core layer 110.

Then, the seed layer 170 may be formed on the upper surface of the solder resist layer 150.

Thereafter, the dry film layer 190 may be formed by stacking a dry film on the upper surface of the seed layer 170.

The holes 210 may be formed by simultaneously drilling the solder resist layer 150, the seed layer 170, and the dry film layer 190.

Here, the solder resist layer 150 may be stacked on the upper surface or the lower surface of the core layer 110.

Next, the copper post bump 230 may be formed by performing the copper filling plating in the holes 210 and removing the seed layer 170 and the dry film layer 190.

Here, the holes 210 may be formed to have the same width in the solder resist layer 150, the seed layer 170, and the dry film layer 190.

In addition, the seed layer 170 and the dry film layer 190 formed on both sides of the hole 210 may be generally removed through the known technology.

According to the technology of the present invention described above, the size of the bump die is reduced, as compared to the case according to the related art, thereby making it possible to form a fine pitch bump.

In addition, the holes are formed to have the same width in the solder resist layer and the dry film layer, thereby making it possible to form a post bump in one unit.

As set forth above, with the board with a fine pitch bump and the method of manufacturing the same according to the exemplary embodiment of the present invention, the holes having the same size are simultaneously drilled into the solder resist layer and the dry film layer to improve a matching degree of the copper post bump, thereby making it possible to form the fine pitch bump.

In addition, with the exemplary embodiment of the present invention, the size of the bump die is reduced, as compared to the case according to the related art, thereby making it possible to form the fine pitch bump.

Although the exemplary embodiments of the present invention have been disclosed for illustrative purposes, those skilled in the art will appreciate that various modifications, additions and substitutions are possible, without departing from the scope and spirit of the invention as disclosed in the accompanying claims. Accordingly, such modifications, additions and substitutions should also be understood to fall within the scope of the present invention.

What is claimed is:

1. A method of manufacturing a board with a fine pitch bump, the method comprising:
forming a solder resist layer by stacking a solder resist on a core layer having a circuit pattern formed thereon;
forming a seed layer on an upper surface of the solder resist layer;
forming a dry film layer by stacking a dry film on an upper surface of the seed layer;
forming holes by simultaneously drilling the solder resist layer, the seed layer, and the dry film layer; and
forming a copper post bump by performing copper filling plating in the holes and removing the seed layer and the dry film layer.

2. The method according to claim 1, wherein the holes are formed to have the same width in the solder resist layer, the seed layer, and the dry film layer.

3. The method according to claim 2, wherein the circuit pattern is formed on an upper surface or a lower surface of the core layer.

4. The method according to claim 3, wherein the solder resist is stacked on an upper surface or a lower surface of the core layer.

5. A board with a fine pitch bump, the board comprising:
a core layer having a circuit pattern formed thereon;
a solder resist layer stacked on an upper surface or a lower surface of the core layer;
a seed layer formed on an upper surface of the solder resist layer;
a dry film layer formed on an upper surface of the seed layer;
holes penetrating through the solder resist layer, the seed layer, and the dry film layer; and
a copper post bump formed by performing copper filling plating in the holes.

6. The board according to claim 5, wherein the holes are formed to have the same width in the solder resist layer, the seed layer, and the dry film layer.

7. The board according to claim 6, wherein the circuit pattern is formed on an upper surface or a lower surface of the core layer.

8. The board according to claim 7, wherein the solder resist layer is stacked on the upper surface or the lower surface of the core layer.
